(19) United States
(12) Patent Application Publication
(10) Pub. No.: US 2025/0266805 A1
(43) Pub. Date: Aug. 21, 2025

(54) ACOUSTIC RESONATOR WITH PISTON MODE PATCHES

(71) Applicant: Qorvo US, Inc., Greensboro, NC (US)

(72) Inventor: Christian Huck, Munich (DE)

(21) Appl. No.: 18/859,434

(22) PCT Filed: Apr. 25, 2023
(86) PCT No.: PCT/US2023/019785

§ 371 Date: Oct. 23, 2024

Related U.S. Application Data
(60) Provisional application No. 63/365,218, filed on May 24, 2022.

(51) Int. Cl. H03H 9/145; H03H 9/02; H03H 9/25

(52) U.S. Cl. CPC H03H 9/1457; H03H 9/02834; H03H 9/25

(57) ABSTRACT

Acoustic resonators with piston mode patches are disclosed. In one aspect, an interdigitated acoustic resonator (300) having plural fingers (308(1)-308(N)) or digits includes a modified piston mode rail. In particular, the piston mode rail is replaced with individual piston mode patches (320(1)-320(N); 322(1)-322(N)) that may be uniform or varied in size. Selection of patch size allows spurious modes to be suppressed to have a smooth filter passband with low overall insertion loss and minimal ripple. Further, the patches may be made through a monolithic process, which reduces overall production cost, complexity and cycle time.

### PRIORITY CLAIM

The present application claims priority to U.S. Provisional Patent Application Ser. No. 63/365,218 filed on May 24, 2022, and entitled “ACOUSTIC RESONATOR WITH PISTON MODE PATCHES,” the contents of which are incorporated herein by reference in its entirety.

### BACKGROUND

### I. Field of the Disclosure

The technology of the disclosure relates generally to acoustic resonators, such as may be used in filters for high-frequency signals.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been an increased need for bandwidth in wireless communication. This need has caused the evolving cellular standards to steadily increase the base frequency at which wireless communications operate. Techniques that work for comparatively low frequencies may not be suitable for higher-frequency applications. Even when certain technologies may be useful at higher frequencies, the technologies may be complicated by the steady reduction in size of electronic circuitry.

One area that has seen frequency and size challenges is in the field of acoustic filters, such as surface acoustic wave (SAW) and bulk acoustic wave (BAW) filters that rely on acoustic resonators. Accordingly, there is room for innovation in this space.

### SUMMARY

Aspects disclosed in the detailed description include acoustic resonators with piston mode patches. In an exemplary aspect, an interdigitated acoustic resonator having plural fingers or digits includes a modified piston mode rail. In particular, the piston mode rail is replaced with individual piston mode patches that may be uniform or varied in size. Selection of patch size allows spurious modes to be rejected to have a smooth filter passband with low overall insertion loss for the acoustic filter and minimal ripple. Further, the patches may be made through a monolithic process, which reduces overall production cost, complexity, and cycle time.

In this regard in one aspect, an acoustic resonator is disclosed. The acoustic resonator comprises a piezoelectric substrate. The acoustic resonator also comprises a first electrode comprising a first plurality of fingers. The acoustic resonator also comprises a second electrode comprising a second plurality of fingers interleaved with the first plurality of fingers. The acoustic resonator also comprises a plurality of piston mode patches associated with the first plurality of fingers. The plurality of piston mode patches has a duty factor less than 100 percent.

In another aspect, an acoustic resonator is disclosed. The acoustic resonator comprises a piezoelectric substrate. The acoustic resonator also comprises a first electrode comprising a first plurality of fingers. The acoustic resonator also comprises a second electrode comprising a second plurality of fingers interleaved with the first plurality of fingers. The acoustic resonator also comprises a first plurality of piston mode patches associated with the first plurality of fingers. The first plurality of piston mode patches has a heterogeneous duty factor.

### BRIEF DESCRIPTION OF THE DRAWINGS

FIG. 1A is a top plan view of a conventional interdigitated acoustic resonator having a piston mode rail;

FIG. 1B is a side elevation cross-sectional view of the acoustic resonator of FIG. 1A taken along line 1B-1B of FIG. 1A;

FIG. 2 provides a series of charts relating to transverse mode suppression relative to piston mode rail thicknesses and duty factors for the acoustic resonator of FIG. 1A across a variety of frequencies;

FIG. 3A is a top plan view of an interdigitated acoustic resonator having piston mode patches according to exemplary aspects of the present disclosure;

FIG. 3B is a side elevation cross-sectional view of the acoustic resonator of FIG. 2A taken along line 3B-3B of FIG. 3A; and

FIG. 4 is a top plan view of an interdigitated acoustic resonator having heterogeneously-sized piston mode patches according to exemplary aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include acoustic resonators with piston mode patches. In an exemplary aspect, an interdigitated acoustic resonator having plural fingers or digits includes a modified piston mode rail. In particular, the piston mode rail is replaced with individual piston mode patches that may be uniform or varied in size. Selection of patch size allows spurious modes to be suppressed to have a smooth filter passband with low overall insertion loss for the acoustic filter and minimal ripple. Further, the patches may be made through a monolithic process, which reduces overall production cost, complexity, and cycle time.

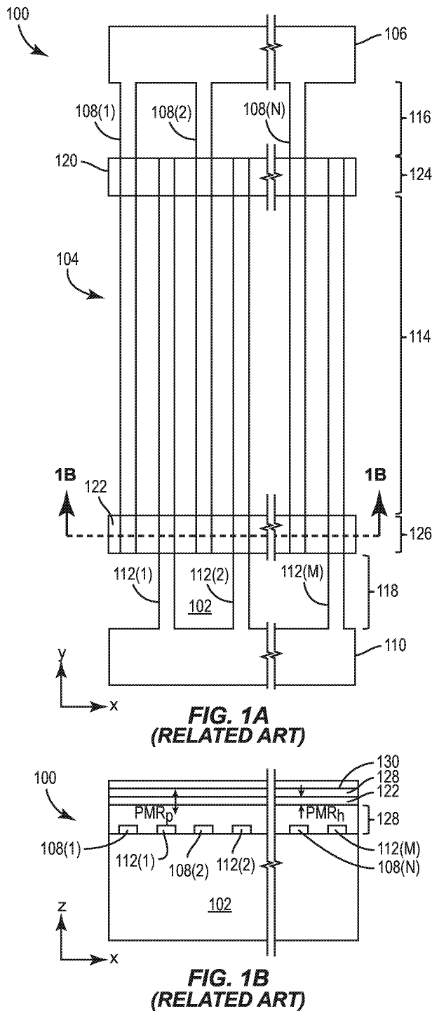

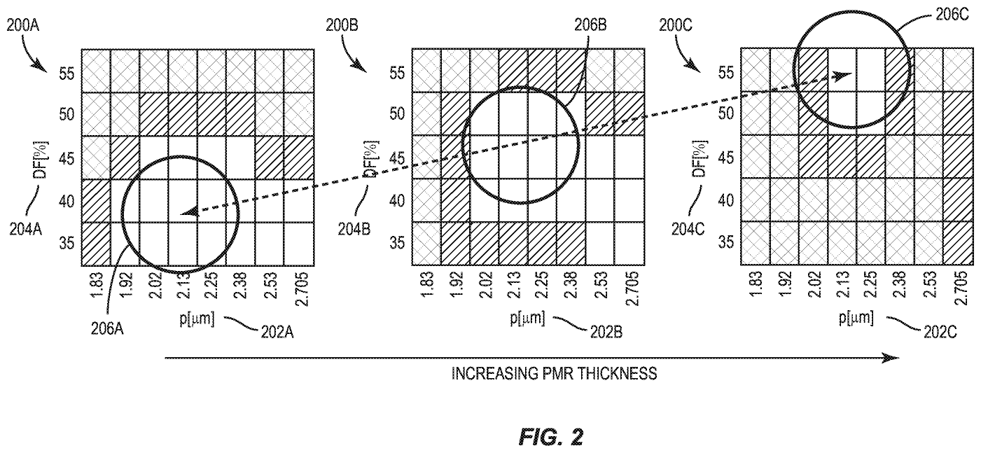

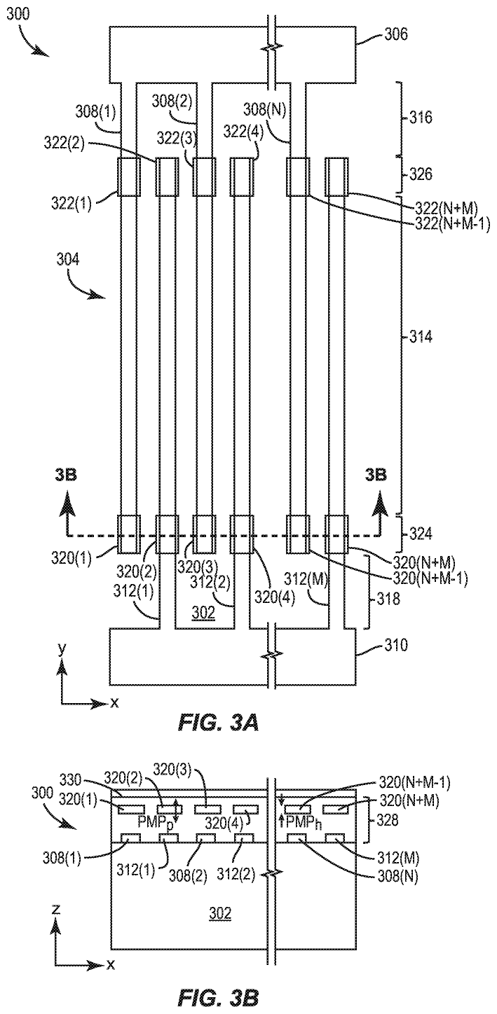

Before addressing exemplary aspects of the present disclosure, a brief overview of a conventional interdigitated acoustic resonator having a piston mode rail and some of its challenges are discussed relative to FIGS. 1A-2. A discussion of exemplary aspects of the present disclosure begins below with reference to FIG. 3A.

Traditionally, acoustic resonators such as surface acoustic wave (SAW) resonators, may rely on two interdigital transducers on a piezoelectric material. The transducers are designed with specific finger width and finger spacing to control desired frequencies of a main mode between the two transducers. In addition to the main mode, there are various spurious modes which impact the performance of a filter using such resonators. One such type of spurious mode is a transverse mode excited in a transverse direction. To confine the acoustic energy in a SAW resonator, a transverse acoustic waveguide is realized by creating velocity barriers outside the transverse ends of the fingers to minimize acoustic leakage in the transverse direction. While effective at confining the acoustic energy, such velocity barriers may create standing waves, which may in turn manifest as peaks inside a resonator stopband resulting in passband ripples of the associated filter.

One approach to reducing these standing waves is a so-called piston mode. A piston mode may be created by modifying a transverse velocity profile (TVP) and introducing a slow region at both transverse ends of the fingers. This slow region may be formed specifically between a main region and a fast region. A common way this slow region is formed is through a piston mode rail, as better seen in FIGS. 1A and 1B.

In this regard, FIG. 1A is top plan view of a SAW resonator 100 while FIG. 1B is a cross-sectional view taken along line 1B-1B. The SAW resonator 100 may include a piezoelectric substrate 102. The piezoelectric substrate 102 may be bulk or layered and may be formed from a material such as quartz, lithium niobate, lithium tantalate, lanthanum gallium silicate, or the like. Further, in layered substrates, additional material including non-piezoelectric material like silicon, silicon carbide, silicon dioxide, or the like may be added to the substrate layer stack. An interdigital structure 104 is positioned on the piezoelectric substrate 102. The SAW resonator 100 may have a longitudinal axis along the x-axis and a lateral transversal axis along the y-axis. A first metal electrode 106 may extend along the longitudinal axis and have fingers 108(1)-108(N) extending along the lateral axis. A second metal electrode 110 may also extend along the longitudinal axis and have fingers 112(1)-112(M) interleaved with the fingers 108(1)-108(N). Signals of interest travel along the x-axis between the fingers 108(1)-108(N) and fingers 112(1)-112(M) as surface waves on the piezoelectric substrate 102.

Most of the signals travel in a main region 114 bounded by fast regions 116, 118 proximate the electrodes 106, 110. The fast regions 116, 118 minimize acoustic leakage in a transverse direction (i.e., along the y-axis), but may create standing transverse waves. Collectively, the main region 114 and fast regions 116, 118 make a TVP for the SAW resonator 100.

Piston mode rails 120, 122 create slow regions 124, 126, respectively, to help mitigate the standing transverse waves. The creation of such slow regions 124, 126 effectively modifies the TVP of the SAW resonator 100. The piston mode rails 120, 122 may be positioned above the fingers 108(1)-108(N), 112(1)-112(M) and separated therefrom by a temperature-compensating (TC) dielectric overcoat layer 128 (e.g., silicon dioxide (SiO2). On top of the TC dielectric overcoat layer 128 there may also be a passivation layer (not shown) formed from a material such as silicon nitride (Si3N4) or the like. The TC dielectric overcoat layer 128 may extend above a top surface (z-axis) of the piston mode rails 120, 122. The piston mode rails 120, 122 are uniform in height or thickness (along the z-axis, denoted PMRh) and width (along the y-axis) and while they may differ from each other, in at least some instances are identical to each other. Another variable is the vertical (z-axis) position of the piston mode rails 120, 122 relative to the fingers 108(1)-108(N), 112(1)-112(M). Likewise, the depth of the piston mode rails 120, 122 relative to a top surface 130 or thickness of the TC dielectric overcoat layer 128 may be varied between different devices, but in a given resonator 100, the depth of the piston mode rail 120 will be the same as the depth of the piston mode rail 122.

By optimizing the variables of the piston mode rails 120, 122, the TVP may be optimized to suppress the transverse modes of the main region. However, even if the transverse modes are suppressed, other spurious modes such as spurious modes with different wave polarization (SMP) may still be present since these spurious modes may require different TVPs to be suppressed. Additionally, the specific TVP selected may induce a hyperbolic mode which is localized and guided in the slow region 124, 126, This hyperbolic mode may manifest as a peak in resonator conductance and a dip in resonator reflection, which degrades the passbands of a filter using the SAW resonator. This degradation may violate insertion loss design criteria and passband ripple criteria. The localized nature of the hyperbolic mode may also contribute to increased self-heating, reduced power handling, and the risk of device failure.

This difference in optimization may be better seen through the graphs 200A-200C of FIG. 2 where, for given pitch (x-axes 202A-202C) and duty factor (y-axis 204A-204C) of the fingers, a sweet spot 206A-206C for different PMR thickness moves around. Since pitch and duty factor may be varied between resonators within a filter, this moving sweet spot makes implementation of a universally-optimal PMR challenging. While PMR thickness could be varied, this approach requires multiple different process steps during manufacturing, adding to cost and complexity and is generally undesirable.

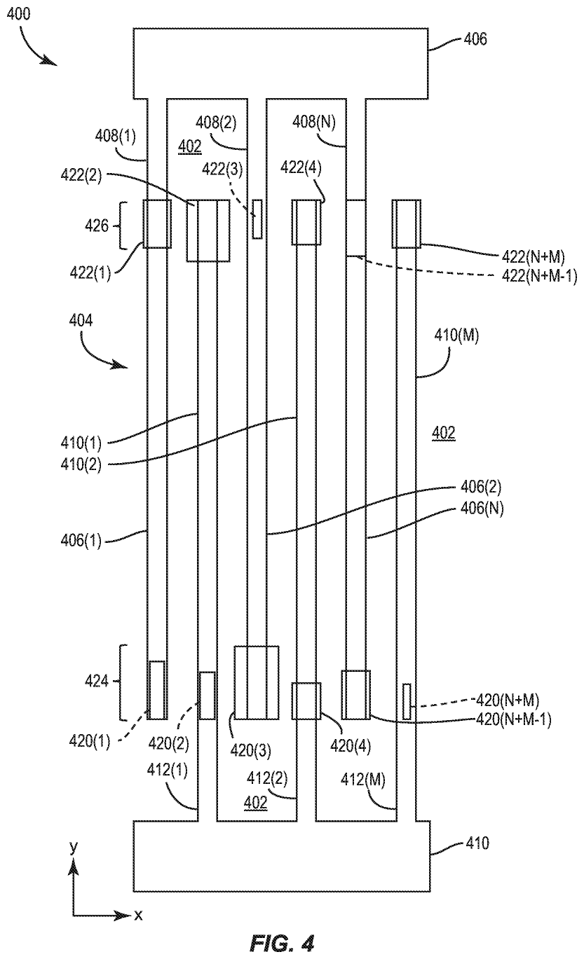

Exemplary aspects of the present disclosure allow for optimization across multiple devices while preserving a monolithic manufacturing process. This improvement is made possible by introducing a duty factor for the piston mode rail to change its longitudinal metallization ratio. In effect, this breaks the piston mode rail into discrete piston mode patches that may have variable duty factors (along the x-axis, although note that pitch may also be varied). Variance in the duty factor between different electrodes (and corresponding fingers) within a device (e.g., resonator, filter, multiplexer, or the like) may change the velocity characteristics of the slow region and thereby reduce spurious modes. Optionally, a width (along the y-axis) may be varied (see FIG. 4) if needed or desired.

By varying these parameters, the TVP may be modified to be optimized at multiple finger pitch and duty factors while holding a thickness of the patches constant, which allows for monolithic processes. Further, the TVP may be varied across different devices (e.g., resonators within a filter) depending on the pitch/duty factor combination all while keeping the thickness constant.

In this regard, FIGS. 3A and 3B illustrate top and side views of a resonator 300. Specifically, FIG. 3A is top plan view of a SAW resonator 300 while FIG. 3B is a cross-sectional view taken along line 3B-3B. The SAW resonator 300 may include a piezoelectric substrate 302. The piezoelectric substrate 302 may be bulk or layered and may be formed from a material such as quartz, lithium niobate, lithium tantalate, lanthanum gallium silicate, or the like. Further, in layered substrates, additional material including non-piezoelectric material like silicon, silicon carbide, silicon dioxide, or the like may be added to the substrate layer stack. An interdigital structure 304 is positioned on the piezoelectric substrate 302. The SAW resonator 300 may have a longitudinal axis along the x-axis and a lateral transverse axis along the y-axis. A first metal electrode 306 may extend along the longitudinal axis and have fingers 308(1)-308(N) extending along the lateral transverse axis. A second metal electrode 310 may also extend along the longitudinal axis and have fingers 312(1)-312(M) interleaved with the fingers 308(1)-308(N). Signals of interest travel along the x-axis between the fingers 308(1)-308(N) and fingers 312(1)-312(M) as surface waves on the piezoelectric substrate 302.

Most of the signals travel in a main region 314 bounded by fast regions 316, 318 proximate the electrodes 306, 310. The fast regions 316, 318 minimize acoustic leakage in a transverse direction (i.e., along the y-axis), but may create standing waves. Collectively, the main region 314 and fast regions 316, 318 make a TVP for the SAW resonator 300.

Instead of piston mode rails, slow regions 324, 326 are created by piston mode patches 320(1)-320(N+M) and 322(1)-322(N+M). That is, the piston mode patches 320(1)-320(N+M) may be on a proximate end of the fingers 312(1)-312(M) and a distal end of the fingers 308(1)-308(N), while the piston mode patches 322(1)-322(N+M) may be on a proximate end of the fingers 308(1)-308(N) and a distal end of the fingers 312(1)-312(M).

As with the piston mode rails 120, 122, the piston mode patches 320(1)-320(N+M), 322(1)-322(N+M) may be positioned above the fingers 308(1)-308(N), 312(1)-312(M) and separated therefrom by a TC dielectric overcoat layer 328. The TC dielectric overcoat layer 328 may extend above a top surface (z-axis) of the piston mode patches 320(1)-320(N+M) and 322(1)-322(N+M). As illustrated, the piston mode patches 320(1)-320(N+M) are uniformly sized relative to one another having a uniform pitch and duty factor and including equal spacing between patches. Likewise, the piston mode patches 322(1)-322(N+M) are uniformly sized relative to one another having a uniform pitch and duty factor and including equal spacing between patches. Further, the piston mode patches 320(1)-320(N+M) may be identical to the piston mode patches 322(1)-322(N+M). Alternatively, the piston mode patches 320(1)-320(N+M) may be different from the piston mode patches 322(1)-322(N+M) in some parameter. However, the thickness (along the z-axis) of the piston mode patches 320(1)-320(N+M) and 322(1)-322(N+M) is uniform so that a monolithic process may be used to create the piston mode patches 320(1)-320(N+M) and 322(1)-322(N+M). Likewise, the vertical position (along the z-axis) of the piston mode patches 320(1)-320(N+M) and 322(1)-322(N+M) relative to the fingers 310(1)-310(N) and 312(1)-312(M) will be uniform, and a depth of the piston mode patches 320(1)-320(N+M) and 322(1)-322(N+M) relative to a top surface 330 of the TC dielectric overcoat layer 328 is also constant.

Further, the dimension along the y-axis is uniform. The piston mode patches 320(1)-320(N+M) and 322(1)-322(N+M) may be a metal or a dielectric material.

To reiterate, the relevant geometric parameters that may be varied are the duty factor (in the longitudinal or x-axis direction) of the piston mode patches 320(1)-320(N+M) and 322(1)-322(N+M); the width (in the transverse or y-axis) of the piston mode patches 320(1)-320(N+M) and 322(1)-322(N+M); the vertical position (z-axis, PMP_p) in the TC dielectric overcoat layer 328; and the z-height/thickness (PMP_h) of the piston mode patches 320(1)-320(N+M) and 322(1)-322(N+M) (i.e., while the thickness is uniform between the piston mode patches 320(1)-320(N+M) and 322(1)-322(N+M), the actual thickness that is used may be selected based on design criteria). Changing these parameters effectuates a change in velocity in the slow regions 324, 326 to achieve the needed velocity reduction for piston mode operation.

It should be appreciated that the duty factor may be varied between approximately one and ninety-nine percent (where 100% would be a continuous rail as shown in FIGS. 1A and 1B) with values between approximately 30-75% being effective to reduce or suppress some hyperbolic spurious modes. Note further that in a device with multiple resonators on a single die (i.e., filter, duplexer, N-in-1 multiplexer), adjustments of parameters may be made for each resonator separately to achieve an overall desired result.

In addition to changing the parameters between different resonators in a single device, it is also possible to change parameters within a single resonator as shown by a SAW resonator 400 in FIG. 4. The SAW resonator 400 may include a piezoelectric substrate 402. The piezoelectric substrate 402 may be bulk or layered and may be formed from a material such as quartz, lithium niobate, lithium tantalate, lanthanum gallium silicate, or the like. Further, in layered substrates, additional material including non-piezoelectric material like silicon, silicon carbide, silicon dioxide, or the like may be added to the substrate layer stack. An interdigital structure 404 is positioned on the piezoelectric substrate 402. The SAW resonator 400 may have a longitudinal axis along the x-axis and a lateral axis along the y-axis. A first metal electrode 406 may extend along the longitudinal axis and have fingers 408(1)-408(N) extending along the lateral axis. A second metal electrode 410 may also extend along the longitudinal axis and have fingers 412(1)-412(M) interleaved with the fingers 408(1)-408(N).

Instead of piston mode rails, slow regions 424, 426 are created by piston mode patches 420(1)-420(N+M) and 422(1)-422(N+M). That is, the piston mode patches 420(1)-420(N+M) may be on a proximate end of the fingers 412(1)-412(M) and a distal end of the fingers 408(1)-408(N), while the piston mode patches 422(1)-422(N+M) may be on a proximate end of the fingers 408(1)-408(N) and a distal end of the fingers 412(1)-412(M).

While the thickness of the piston mode patches 420(1)-420(N+M) and 422(1)-422(N+M) is constant, the duty factor, the height (y-axis), and the width (x-axis) may be varied or otherwise made heterogenous to achieve a desired TVP with desired mode suppression.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. An acoustic resonator comprising:
a piezoelectric substrate;
a first electrode comprising a first plurality of fingers;
a second electrode comprising a second plurality of fingers interleaved with the first plurality of fingers; and
a plurality of piston mode patches associated with the first plurality of fingers, each of the plurality of piston mode patches being part of a piston mode rail with a longitudinal metallization ratio having a duty factor less than 100 percent, and each of the plurality of piston mode patches having a lateral dimension which is non-uniform relative to at least one other of the plurality of piston mode patches.

2. The acoustic resonator of claim 1, wherein each of the plurality of piston mode patches is positioned above respective proximate ends of the first plurality of fingers.

3. The acoustic resonator of claim 1, wherein each of the plurality of piston mode patches is positioned above respective distal ends of the first plurality of fingers.

4. The acoustic resonator of claim 1, wherein each of the plurality of piston mode patches comprises a uniform thickness.

5. The acoustic resonator of claim 1, wherein the plurality of piston mode patches is configured to create a slow region in the acoustic resonator and contribute to a transverse velocity profile (TVP) to suppress transverse modes.

6. The acoustic resonator of claim 1, wherein the plurality of piston mode patches is further configured to suppress spurious modes in the acoustic resonator.

7. The acoustic resonator of claim 1, further comprising:
a temperature-compensating (TC) dielectric overcoat layer positioned above the first electrode and enveloping the plurality of piston mode patches; and
a passivation layer on top of the TC dielectric overcoat layer.

8. The acoustic resonator of claim 1, further comprising a second plurality of piston mode patches associated with the second plurality of fingers, the second plurality of piston mode patches having a second duty factor less than 100 percent.

9. The acoustic resonator of claim 8, wherein the second duty factor is the same as the duty factor.

10. The acoustic resonator of claim 8, wherein each of the second plurality of piston mode patches is positioned above respective proximate ends of the second plurality of fingers.

11. The acoustic resonator of claim 8, wherein each of the second plurality of piston mode patches is positioned above respective distal ends of the second plurality of fingers.

12. The acoustic resonator of claim 1, wherein the piezoelectric substrate is either a bulk substrate or a layered substrate.

13. The acoustic resonator of claim 1, wherein the plurality of piston mode patches comprise metal patches.

14. An acoustic resonator comprising:
a piezoelectric substrate;
a first electrode comprising a first plurality of fingers;
a second electrode comprising a second plurality of fingers interleaved with the first plurality of fingers; and
a first plurality of piston mode patches associated with the first plurality of fingers, each of the plurality of piston mode patches being part of a piston mode rail with a longitudinal metallization ratio having a heterogeneous duty factor, and each of the plurality of piston mode patches having a lateral dimension which is non-uniform relative to at least one other of the plurality of piston mode patches.

15. The acoustic resonator of claim 14, further comprising a second plurality of piston mode patches associated with the second plurality of fingers, the second plurality of piston mode patches having a heterogeneous duty factor.

16. The acoustic resonator of claim 14, further comprising:
a temperature-compensating (TC) dielectric overcoat layer positioned above the first electrode and enveloping the first plurality of piston mode patches; and
a passivation layer on top of the TC dielectric overcoat layer.

17. The acoustic resonator of claim 14, wherein the first plurality of piston mode patches comprises a plurality of heterogeneous heights.

18. The acoustic resonator of claim 14, wherein the first plurality of piston mode patches comprises a plurality of heterogeneous widths.

19. The acoustic resonator of claim 14, wherein the first plurality of piston mode patches comprises a uniform thickness.

20. The acoustic resonator of claim 14, wherein the piezoelectric substrate is either a bulk substrate or a layered substrate.
